(19) United States
(12) Patent Application Publication
(10) Pub. No.: US 2026/0258277 A1
(43) Pub. Date: Sep. 3, 2026

(54) RESIN COMPOSITION FOR OPTICAL WAVEGUIDES, DRY FILM FOR OPTICAL WAVEGUIDES, AND OPTICAL WAVEGUIDE

(71) Applicant: Panasonic Intellectual Property Management Co., Ltd., Osaka (JP)

(72) Inventors: Toru ENDO, Osaka (JP); Toru NAKASHIBA, Osaka (JP)

(73) Assignee: Panasonic Intellectual Property Management Co., Ltd., Osaka (JP)

(21) Appl. No.: 19/163,127

(22) PCT Filed: Feb. 19, 2024
(86) PCT No.: PCT/JP2024/005849

§ 371 Date: Sep. 8, 2025

(30) Foreign Application Priority Data
Mar. 10, 2023 (JP) 2023-037865

(51) Int. Cl. C09D 175/12; C09D 4/06; G02B 1/04; G02B 6/10

(52) U.S. Cl. CPC C09D 175/12; C09D 4/06; G02B 1/04; G02B 6/10

(57) ABSTRACT

A resin composition for use in optical waveguides contains an epoxy resin (A), a (meth)acylate resin (B), and a photopolymerization initiator (C). The (meth)acrylate resin (B) includes: a first (meth)acrylate compound (B-1) having a structural unit expressed by the following formula (1) and a structural unit expressed by the following formula (2); and a second (meth)acrylate compound (B-2) different from the first (meth)acrylate compound (B-1). The content of the first (meth)acrylate compound (B-1) is equal to or greater than 5% by mass and equal to or less than 20% by mass with respect to an entire mass of the epoxy resin (A) and the (meth)acrylate resin (B):

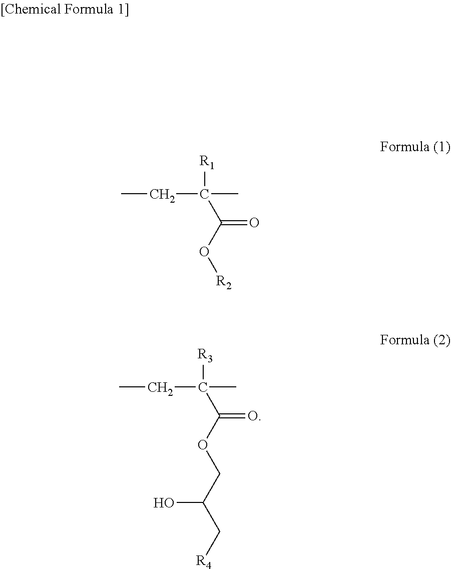

In formulae (1) and (2), R₁ to R₃ are each independently an alkyl group having 1 to 3 carbon atoms or a hydrogen atom, and R₄ is an acryloyl group or a methacryloyl group.

### TECHNICAL FIELD

The present disclosure relates to a resin composition for use in optical waveguides, a dry film for use in optical waveguides, and an optical waveguide.

### BACKGROUND ART

In the field of middle-range communications such as fiber to the home (FTTH) and onboard equipment, a fiber-optic cable is used as a transmission medium. In the field of short-range communications, however, there is a growing demand for high-density wiring that has a narrow pitch, branches, intersections, and multilayer structure, for example, which are difficult to realize by a fiber-optic cable. Thus, an optical wiring board including an optical waveguide that may satisfy all of these requirements and a hybrid optical-electrical board including an electric circuit have been proposed to meet such a demand.

Examples of optical waveguides include a polymer optical waveguide which uses a resin material. The optical waveguide provided for a hybrid optical-electrical board is preferably the polymer optical waveguide, considering its compatibility with a wiring board including an electric circuit.

A development step is one of the process steps of forming the polymer optical waveguide. Alkaline development which uses an alkaline aqueous solution as a developer is one of the development methods. As used herein, the “alkaline development” refers to a method for making development by dissolving an uncured resin composition, which is not necessary for forming an optical waveguide, in an alkaline solution. According to this method, the resin composition for use to form the optical waveguide needs to have excellent solubility in an alkaline aqueous solution (alkaline developability).

Examples of materials for such an optical waveguide include a resin composition for use to mold an optical waveguide, which uses a resin containing: a polymer (A) having a carboxyl group, a (meth)acrylate (B), a photoradical polymerization initiator (C), and a phenolic antioxidant (D), as described in Patent Literature 1.

### CITATION LIST

### Patent Literature

Patent Literature 1: JP 5771978 B2

### SUMMARY OF INVENTION

A resin composition according to an aspect of the present disclosure is designed for use in optical waveguides. The resin composition contains an epoxy resin (A), a (meth)acylate resin (B), and a photopolymerization initiator (C). The (meth)acrylate resin (B) includes: a first (meth)acrylate compound (B-1) having a structural unit expressed by the following formula (1) and a structural unit expressed by the following formula (2); and a second (meth)acrylate compound (B-2) different from the first (meth)acrylate compound (B-1). The content of the first (meth)acrylate compound (B-1) is equal to or greater than 5% by mass and equal to or less than 20% by mass with respect to an entire mass of the epoxy resin (A) and the (meth)acrylate resin (B). The content of the second (meth)acrylate compound (B-2) is equal to or greater than 30% by mass and equal to or less than 60% by mass with respect to the entire mass of the epoxy resin (A) and the (meth)acrylate resin (B).

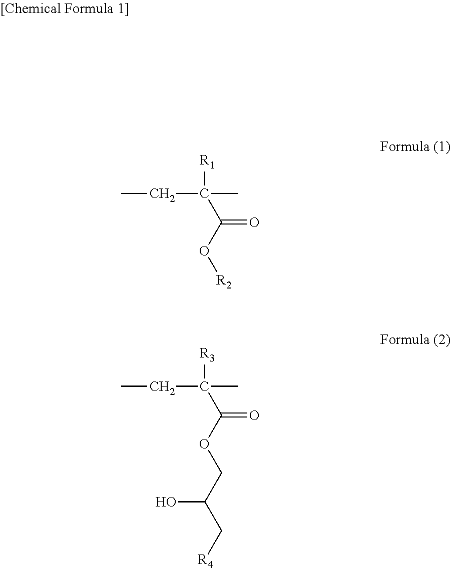

In formulae (1) and (2), R₁ to R₃ are each independently an alkyl group having 1 to 3 carbon atoms or a hydrogen atom, and R₄ is an acryloyl group or a methacryloyl group.

A dry film according to another aspect of the present disclosure is designed for use in optical waveguides. The dry film includes a resin layer containing either the resin composition described above for use in optical waveguides or a semi-cured product of the resin composition for use in optical waveguides.

An optical waveguide according to still another aspect of the present disclosure includes a core and a cladding layer that covers the core. At least one of the core or the cladding layer contains a cured product of the resin composition described above for use in optical waveguides.

A resin composition for use in optical waveguides according to the present disclosure achieves excellent alkaline developability and low tackiness at the same time.

### BRIEF DESCRIPTION OF DRAWINGS

FIG. 1 is a cross-sectional view illustrating a configuration for a dry film for use in optical waveguides according to an exemplary embodiment;

FIG. 2A illustrates a method for manufacturing a hybrid optical-electrical board including an optical waveguide according to the exemplary embodiment;

FIG. 2B illustrates the method for manufacturing the hybrid optical-electrical board including the optical waveguide according to the exemplary embodiment;

FIG. 2C illustrates the method for manufacturing the hybrid optical-electrical board including the optical waveguide according to the exemplary embodiment;

FIG. 2D illustrates the method for manufacturing the hybrid optical-electrical board including the optical waveguide according to the exemplary embodiment;

FIG. 3A illustrates the method for manufacturing the hybrid optical-electrical board including the optical waveguide according to the exemplary embodiment;

FIG. 3B illustrates the method for manufacturing the hybrid optical-electrical board including the optical waveguide according to the exemplary embodiment;

FIG. 3C illustrates the method for manufacturing the hybrid optical-electrical board including the optical waveguide according to the exemplary embodiment; and

FIG. 3D illustrates the method for manufacturing the hybrid optical-electrical board including the optical waveguide according to the exemplary embodiment.

### DESCRIPTION OF EMBODIMENTS

In order to improve the alkaline developability of a resin composition used, it is preferable that resin components with relatively small molecular weights be used in profusion. However, as the proportion of such resin components with small molecular weights increases, the alkaline developability is likely to improve, but the tackiness tends to increase when the resin components are processed into a dry film, for example. As the tackiness increases, the dry film becomes sticky to cause a decline in its processability. In order to reduce the tackiness, it is preferable that a solid resin component with a relatively large molecular weight be used. Therefore, it is not easy to achieve both excellent alkaline developability and low tackiness.

The present disclosure provides a resin composition for use in optical waveguides, a dry film for use in optical waveguides, and an optical waveguide, all of which have excellent alkaline developability and low tackiness.

### 1. Resin Composition for Use in Optical Waveguides

A resin composition according to an aspect of the present disclosure is designed for use in optical waveguides. The resin composition contains an epoxy resin (A), a (meth)acylate resin (B), and a photopolymerization initiator (C). The (meth)acrylate resin (B) includes: a first (meth)acrylate compound (B-1) having a structural unit expressed by the following formula (1) and a structural unit expressed by the following formula (2); and a second (meth)acrylate compound (B-2) different from the first (meth)acrylate compound (B-1).

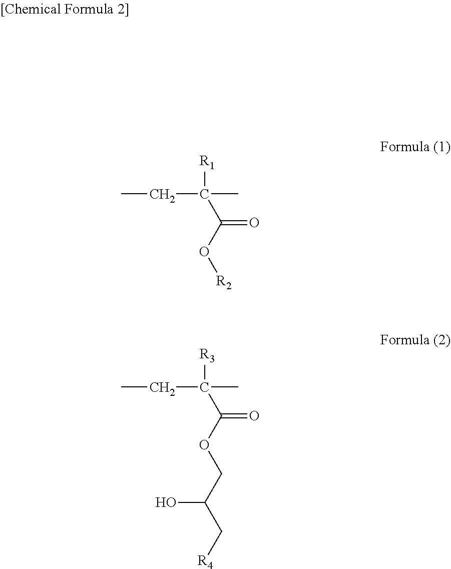

The content of the first (meth)acrylate compound (B-1) is equal to or greater than 5% by mass and equal to or less than 20% by mass with respect to an entire mass of the epoxy resin (A) and the (meth)acrylate resin (B). The content of the second (meth)acrylate compound (B-2) is equal to or greater than 30% by mass and equal to or less than 60% by mass with respect to the entire mass of the epoxy resin (A) and the (meth)acrylate resin (B).

This resin composition for use in optical waveguides has excellent alkaline developability and low tackiness.

As used herein, the “alkaline developability” means that the resin composition exhibits excellent solubility in an alkaline developer used in general alkaline development. That is to say, the excellent alkaline developability means that when an optical waveguide is formed, unnecessary uncured parts may be easily removed by using an alkaline developer.

Examples of the developer include, without limitation, potassium hydroxide, sodium hydroxide, sodium carbonate, potassium carbonate, sodium phosphate, sodium silicate, ammonia, and amines. Any developing method may be used without limitation as long as the method may be used to remove the uncured portion. Examples of the developing methods include dipping, showering, spraying, and brushing.

As used herein, the term “low tackiness” means that the surface of the dry film for use in optical waveguides does not have excessive stickiness when the resin composition is processed into a dry film for use in optical waveguides. As the tackiness increases, some problems will occur. For example, when a protective film stacked on the resin layer 1 of the dry film for use in optical waveguides is peeled off, a part of the resin layer 1 will adhere to the protective film, thus making the surface uneven and causing loss of planarity.

### <Epoxy Resin (A)>

The epoxy resin (A) contains an epoxy compound having photocurability and high transparency. It is preferable that the epoxy resin (A) contain at least one selected from the group consisting of solid bisphenol A epoxy compounds (A-1), liquid bisphenol A epoxy compounds (A-2), and polyfunctional aromatic epoxy compounds (A-3) having three or more epoxy groups per molecule on average. It is preferable that the epoxy resin (A) contain all of the solid bisphenol A epoxy compound (A-1), the liquid bisphenol A epoxy compound (A-2), and the polyfunctional aromatic epoxy compound (A-3) having three or more epoxy groups per molecule on average.

The solid bisphenol A epoxy compound (A-1) is a bisphenol A epoxy compound that is solid at 25° C. and has one or two epoxy groups per molecule. Using the solid bisphenol A epoxy compound (A-1) allows an optical waveguide having transparency and a high glass transition temperature to be formed.

The lower limit value of the epoxy equivalent of the solid epoxy bisphenol A epoxy compound (A-1) is not limited to any particular value, but is preferably equal to or greater than 400 g/eq, and more preferably equal to or greater than 670 g/eq. The upper limit value thereof is preferably equal to or less than 1500 g/eq, and more preferably equal to or less than 1100 g/eq. If the epoxy equivalent were too small or too large, it would be difficult to form an optical waveguide. Specifically, if the epoxy equivalent were too small, it would be difficult to form a dry film. If the epoxy equivalent were too large, then the developability would deteriorate too significantly to have development done as intended when the core 11 and cladding layer 8 of the optical waveguide are formed. For these reasons, setting the epoxy equivalent of the solid bisphenol A epoxy compound (A-1) at a value falling within this range allows an optical waveguide to be formed advantageously.

Examples of the solid bisphenol A epoxy compound (A-1) include 1001, 1002, 1003, 1055, 1004, 1004AF, 1003F, 1004F, 1005F, 1004FS, 1006FS, and 1007FS, all of which are manufactured by Mitsubishi Chemical Corporation. Also, as the solid bisphenol A epoxy compound (A-1), any of the compounds exemplified above may be used by itself, or two or more compounds selected from those compounds may be used in combination, whichever is appropriate.

The lower limit value of the content of the solid bisphenol A epoxy compound (A-1) is preferably equal to or greater than 40% by mass, more preferably equal to or greater than 45% by mass, with respect to the entire mass of the epoxy resin (A). The upper limit value of the content of the solid bisphenol A epoxy compound (A-1) is preferably equal to or less than 60% by mass, more preferably equal to or less than 55% by mass, with respect to the entire mass of the epoxy resin (A). If the content of the solid bisphenol A epoxy compound (A-1) were too little or too much, then it would be difficult to form the optical waveguide. Specifically, if the content of the solid bisphenol A epoxy compound (A-1) were too little, then a decline would be caused in the flexibility of a dry film made of the resin composition for optical waveguides when the optical waveguide is formed. On the other hand, if the content of the solid bisphenol A epoxy compound (A-1) were too much, then the cured product thereof would have too low a degree of heat resistance to avoid becoming brittle. In view of these considerations, an advantageous optical waveguide may be formed as long as the content of the solid bisphenol A epoxy compound (A-1) falls within the above-defined range.

The liquid bisphenol A epoxy compound (A-2) is a bisphenol A epoxy compound which is liquid at 25° C. and has one or two epoxy groups in one molecule. Using the liquid bisphenol A epoxy compound (A-2) enhances the alkaline developability.

The lower limit value of the viscosity of the liquid bisphenol A epoxy compound (A-2) at 25° C. is not limited to any particular value. Specifically, the lower limit value is preferably equal to or greater than 100 mPa·s, and more preferably equal to or greater than 2000 mPa·s. The upper limit value is preferably equal to or less than 20,000 mPa·s, more preferably equal to or less than 17,000 mPa·s.

Specific examples of the liquid bisphenol A epoxy compound (A-2) include 840, 840-S, 850, 850-S, and EXA-850CRP, all of which are manufactured by DIC Corporation.

As the liquid bisphenol A epoxy compound (A-2), any of the compounds exemplified above may be used by itself, or two or more compounds selected from these compounds may be used in combination, whichever is appropriate.

The number average molecular weight of the liquid bisphenol A epoxy compound (A-2) is preferably smaller than the number average molecular weight of the second (meth)acrylate compound (B-2) to be described below, and more specifically, is preferably less than 3,000, more preferably equal to or less than 1,000, and even more preferably equal to or less than 500. The upper limit value of the number average molecular weight is not limited to any particular value but is equal to or greater than 200.

Setting the number average molecular weight at a value falling within this range makes it easier to mix the liquid bisphenol A epoxy compound (A-2) and the second (meth)acrylate compound (B-2) together, thus improving the alkali developability of the resin composition for optical waveguides.

The lower limit value of the content of the liquid bisphenol A epoxy compound (A-2) is preferably equal to or greater than 15% by mass, more preferably equal to or greater than 20% by mass, with respect to the entire mass of the epoxy resin (A). The upper limit value of the content of the liquid bisphenol A epoxy compound (A-2) is preferably equal to or less than 35% by mass, more preferably equal to or less than 30% by mass, with respect to the entire mass of the epoxy resin (A). If the content of the liquid bisphenol A epoxy compound (A-1) were too little or too much, it would be difficult to form an optical waveguide.

The polyfunctional aromatic epoxy compound (A-3) is not limited to any particular compound, as long as the polyfunctional aromatic epoxy compound (A-3) is an aromatic epoxy compound having three or more epoxy groups per molecule. Specific examples of the polyfunctional aromatic epoxy compound (A-3) include 2-[4-(2,3-epoxypropoxy)phenyl]-2-[4-[1,1-bis[4-([2,3-epoxypropoxy]phenyl)]ethyl]phenyl]propane. Examples of the polyfunctional aromatic epoxy compound (A-3) include VG3101 manufactured by Printec Co.

The lower limit value of the content of the polyfunctional aromatic epoxy compound (A-3) is preferably equal to or greater than 15% by mass, more preferably equal to or greater than 20% by mass, with respect to the entire mass of the epoxy resin (A). The upper limit value of the content of the polyfunctional aromatic epoxy compound (A-3) is preferably equal to or less than 35% by mass, more preferably equal to or less than 30% by mass, with respect to the entire mass of the epoxy resin (A). If the content of the polyfunctional aromatic epoxy compound (A-3) were too little or too much, the heat resistance and mechanical strength of the optical waveguides might decrease.

Specifically, setting the content of the polyfunctional aromatic epoxy compound (A-3) at too small a value could cause a decline in the heat resistance of the resultant cured product. Setting the content of the polyfunctional aromatic epoxy compound (A-3) at too large a value might make the cured product rather brittle. For these reasons, a suitable optical waveguide may be formed as long as the content of the polyfunctional aromatic epoxy compound (A-3) falls within the above-defined range.

Optionally, other epoxy compounds may be used unless the advantages of this embodiment are impaired.

### <(Meth)acrylate Resin (B)>

The (meth)acrylate resin (B) contains a first (meth)acrylate compound (B-1) having a structural units expressed by the following formula (1) and a structural unit expressed by the following formula (2), and a second (meth)acrylate compound (B-2) different from the first (meth)acrylate compound (B-1).

The content of the (meth)acrylate resin (B) is not limited to any particular value, but is preferably equal to or greater than 35% by mass and equal to or less than 90% by mass, more preferably equal to or greater than 45% by mass and equal to or less than 80% by mass, and even more preferably equal to or greater than 55% by mass and equal to or less than 70% by mass, with respect to the entire mass of the epoxy resin (A) and the (meth)acrylate resin (B). Setting the content of the (meth)acrylate resin (B) at a value falling within this range allows a dry film to be formed advantageously and allows the composition to have excellent alkaline developability.

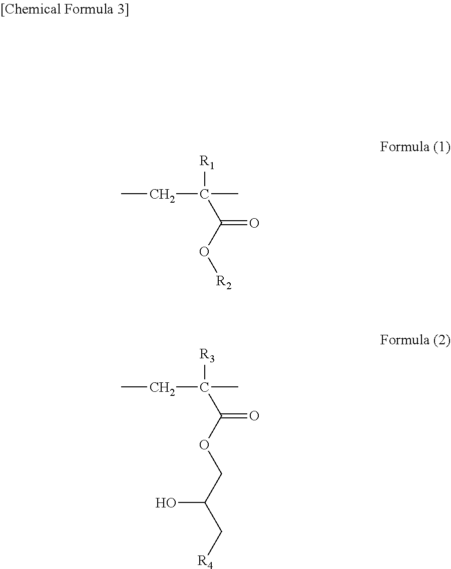

The first (meth)acrylate compound (B-1) has a structural unit expressed by the formula (1) and a structural unit expressed by the formula (2).

In the formula (1), R₁ to R₃ are each independently either an alkyl group having 1 to 3 carbon atoms or a hydrogen atom. In the formula (2), R₄ represents an acryloyl group or a methacryloyl group.

Using such a (meth)acrylate resin (B) allows for reducing the tackiness when the resin composition is processed into a dry film, for example. Reducing the tackiness not only allows the manufacturing process of an optical waveguide to be performed more efficiently but also enables fine-line processing as well.

Each of R₁ to R₃ is preferably an alkyl group having 1 to 3 carbon atoms, more preferably a methyl group. Using such a substituent group allows the tackiness to be further reduced.

Supposing the average number of structural units expressed by the formula (1) which are contained in one molecule of the first (meth)acrylate compound (B-1) is m and the average number of structural units expressed by the formula (2) which are contained in one molecule of the first (meth)acrylate compound (B-1) is n, the lower limit value of the m/n ratio is preferably equal to or greater than 1, more preferably equal to or greater than 1.2, even more preferably equal to or greater than 1.5, and most preferably equal to or greater than 1.9. The upper limit value of the m/n ratio is preferably equal to or less than 9, more preferably equal to or less than 7, and even more preferably equal to or less than 5. Using such a first (meth)acrylate compound (B-1) allows the tackiness to be further reduced.

In the formulae (1) and (2), each of R₁ to R₃ is preferably an alkyl group having 1 to 3 carbon atoms, and more preferably a methyl group. In the formula (2), R₄ is preferably an acryloyl group. That is to say, the first (meth)acrylate compound (B-1) preferably contains a structural unit expressed by the following formula (3) and a structural unit expressed by the following formula (4). Using such a (meth)acrylate compound (B-11) allows the tackiness to be reduced.

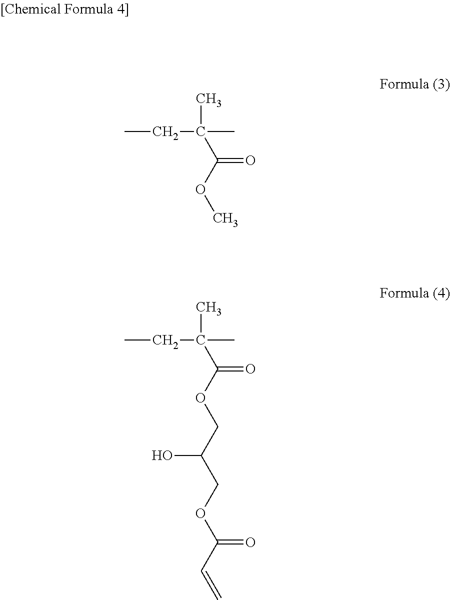

The number average molecular weight of the first (meth)acrylate compound (B-1) is not limited to any particular value, but the specific lower limit value thereof is preferably equal to or greater than 3,000, and more preferably equal to or greater than 4,000. The upper limit value thereof is preferably equal to or less than 8,000, and more preferably equal to or less than 6,000. Setting the number average molecular weight of the first (meth)acrylate compound (B-1) at a value falling within this range allows the tackiness to be reduced.

The lower limit value of the content of the first (meth)acrylate compound (B-1) is preferably equal to or greater than 5% by mass, and more preferably equal to or greater than 7% by mass, with respect to the entire mass of the epoxy resin (A) and the (meth)acrylate resin (B). The upper limit value thereof is preferably equal to or less than 20% by mass, and more preferably equal to or less than 15% by mass. Setting the content of the first (meth)acrylate compound (B-1) at a value falling within this range allows the alkali developability to be improved and allows the tackiness to be reduced.

As the first (meth)acrylate compound (B-1), only one type of compound may be used by itself or two or more types of compounds may be used in combination, whichever is appropriate.

Adding the second (meth)acrylate compound (B-2) improves the developability in the alkali development process. In addition, this also allows a cured product of the resin composition for optical waveguides to exhibit a high refractive index and a high glass transition temperature. Consequently, this allows a suitable optical waveguide to be formed.

The content of the second (meth)acrylate compound (B-2) is equal to or greater than 30% by mass and equal to or less than 80% by mass with respect to the entire mass of the epoxy resin (A) and the (meth)acrylate resin (B). The lower limit value thereof is preferably equal to or greater than 35% by mass and more preferably equal to or less than 45% by mass. The upper limit value thereof is preferably equal to or less than 65% by mass and more preferably equal to or less than 60% by mass. Setting the content of the second (meth)acrylate compound (B-2) at a value falling within this range allows the alkaline developability to be improved.

The second (meth)acrylate compound (B-2) is not limited to any particular compound unless the alkali developability is impaired, but preferably contains a urethane (meth)acrylate compound (B-21) or a bisphenol A (meth)acrylate compound (B-22) obtained by allowing an epoxy (meth)acrylate compound to react with a diisocyanate compound and a diol compound having a carboxy group, and preferably contains a urethane (meth)acrylate compound (B-21) and a bisphenol A (meth)acrylate compound (B-22). Also, the epoxy (meth)acrylate compound more preferably has two or more hydroxy groups and ethylenically unsaturated groups per molecule on average.

The urethane (meth)acrylate compound (B-21) preferably has a larger number average molecular weight than the liquid bisphenol A epoxy compound (A-2). Specifically, the number average molecular weight of the urethane (meth)acrylate compound (B-21) is preferably equal to or greater than 3,000, more preferably equal to or greater than 5,000, and even more preferably equal to or greater than 8,000. Furthermore, the upper limit value thereof is preferably equal to or less than 30,000, more preferably equal to or less than 20,000, and even more preferably equal to or less than 15,000.

Setting the number average molecular weight of the urethane (meth)acrylate compound (B-21) at a value falling within this range allows a dry film to be formed advantageously and thereby allows the resin composition to have excellent alkaline developability. Furthermore, setting the number average molecular weight of the urethane (meth)acrylate compound (B-21) at a value larger than the number average molecular weight of the liquid bisphenol A epoxy compound (A-2) makes it easier to mix the liquid bisphenol A epoxy compound (A-2) and the second (meth)acrylate compound (B-2) together, thus further improving the alkaline developability.

As an example of the above-mentioned urethane (meth)acrylate compound (B-21), a compound having a structural unit expressed by the following formula (5) may be used:

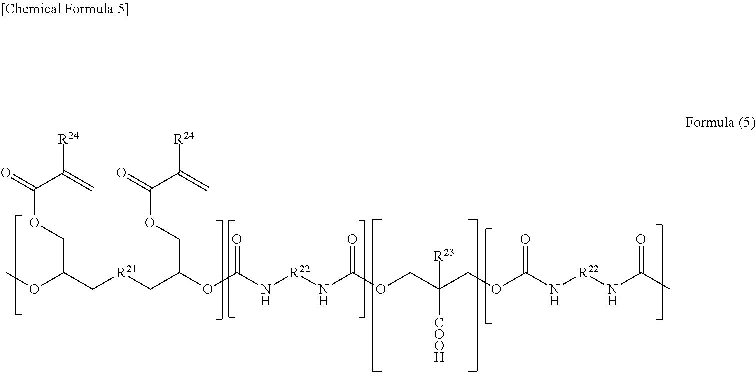

In this formula (5), R₂₁ to R₂₄ are independent of each other, R₂₁ is a residue of epoxy (meth)acrylate, R₂₂ is a residue of diisocyanate, R₂₃ is an alkyl group having 1 to 5 carbon atoms derived from the material diol, and R₂₄ is a hydrogen atom or a methyl group. As used herein, the “residue” refers to the structure of a part of each material component that will remain when a functional group used for bonding is removed from the material component.

R₂₁ in the formula (5) is preferably a skeleton having a phenyl group and is more preferably a bisphenol A skeleton.

Using the urethane (meth)acrylate compound (B-21) having such a structure allows the toughness and elasticity of the dry film thus formed to be improved, thus improving the moldability of the dry film and the optical waveguide. In addition, this allows the glass transition temperature to be increased and also allows the heat resistance to be increased.

Examples of the urethane (meth)acrylate compound (B-21) include UXE-3011, UXE-3012, and UXE-3024, all of which are manufactured by Nippon Kayaku Co., Ltd. As the urethane (meth)acrylate compound (B-21), any of the compounds exemplified above may be used by itself, or two or more compounds selected from those compounds may be used in combination, whichever is appropriate.

The content of the urethane (meth)acrylate compound (B-21) is equal to or greater than 20% by mass and equal to or less than 60% by mass with respect to the entire mass of the epoxy resin (A) and the (meth)acrylate resin (B). The lower limit value thereof is preferably equal to or greater than 30% by mass. The upper limit value thereof is preferably equal to or less than 50% by mass and more preferably equal to or less than 40% by mass. Setting the content of the urethane (meth)acrylate compound (B-21) at a value falling within this range improves the alkali developability.

The bisphenol A (meth)acrylate compound (B-22) is a bisphenol A (meth)acrylate compound having one or two acryloyl and methacryloyl groups in total per molecule. Using the bisphenol A (meth)acrylate compound (B-22) allows an optical waveguide having high transparency to be formed.

The bisphenol A (meth)acrylate compound (B-22) preferably has one epoxy group on average per molecule. That is to say, the bisphenol A (meth)acrylate compound (B-22) preferably has one acryloyl or methacryloyl group on average per molecule, and more preferably has one acryloyl group. This allows such a bisphenol A (meth)acrylate compound (B-22) to react with a carboxy group and an epoxy group. Consequently, this allows for increasing not only the degree of curing of the resin composition for optical waveguides but also the heat resistance as well. The number average molecular weight of the bisphenol A (meth)acrylate compound (B-22) is preferably equal to or less than 2,000, and more preferably equal to or less than 1,000. Although not limited to any particular value, the number average molecular weight of the bisphenol A (meth)acrylate compound (B-22) is preferably equal to or greater than 200.

Examples of the bisphenol A (meth)acrylate compound (B-22) include EA-1010N, EA-1010LC, EA-1010NT2, and EA-1020LC3, all of which are manufactured by Shin-Nakamura Chemical Co., Ltd. In addition, as the bisphenol A (meth)acrylate compound (B-22), any of the compounds exemplified above may be used by itself, or two or more compounds selected from those compounds may be used in combination, whichever is appropriate.

The lower limit value of the content of the bisphenol A (meth)acrylate compound (B-22) is preferably equal to or greater than 5% by mass, and more preferably equal to or greater than 7% by mass, with respect to the entire mass of the epoxy resin (A) and the (meth)acrylate resin (B). The upper limit value is preferably equal to or less than 20% by mass, and more preferably equal to or less than 18% by mass. Setting the content of the bisphenol A (meth)acrylate compound (B-22) at a value falling within this range allows the heat resistance to be improved.

In addition, the (meth)acrylate resin (B) may be a (meth)acrylate compound other than the compounds exemplified above, unless the advantages of this embodiment are impaired. For example, (meth)epoxy acrylate compounds and acrylate monomers used in the application of general optical waveguide with alkaline developability may be used. In particular, it is preferable that the (meth)acrylate resin (B) include an acrylate monomer which is expected to be used effectively as a crosslinking agent. The acrylate monomer preferably has two or more (meth)acryloyl groups per molecule on average, and more preferably has three or more (meth)acryloyl groups per molecule. Such a monomer crosslinking agent may increase the alkaline developability of the resin composition for optical waveguides and may increase the crosslink density of the cured product.

The number average molecular weight of the monomer crosslinking agent is preferably equal to or less than 1,000, and more preferably equal to or less than 500. The lower limit value thereof is not limited to any particular value, but is preferably equal to or greater than 100, for example.

Examples of the crosslinking agents having a (meth)acryloyl group include trimethylol propane triacrylate.

### <Photopolymerization Initiator (C)>

The photopolymerization initiator (C) is not limited to any particular compound as long as the photopolymerization initiator (C) is a compound having the ability to promote curing of the resin composition for optical waveguides by irradiating the resin composition for optical waveguides with light having a specific wavelength.

Specific examples of the photopolymerization initiator (C) include an acylphosphine oxide compound (C-1), an oxime ester compound having an oxime ester group, α-aminoacetophenone compound, a titanocene compound, a benzoin compound, an acetophenone compound, an anthraquinone compound, a thioxanthone compound, a ketal compound, a benzophenone compound, a tertiary amine compound, and a xanthone compound. It is preferable that the photopolymerization initiator (C) be the acylphosphine oxide compound (C-1).

Using such a photopolymerization initiator (C) allows the curability of the resin composition for optical waveguides to be improved.

Examples of the acylphosphine oxide compound (C-1) include bisacylphosphine oxide-based photopolymerization initiators and monoacylphosphine oxide-based photopolymerization initiators. Specific examples of the acylphosphine oxide compound (C-1) include bis-(2,6-dichlorobenzoyl)phenylphosphine oxide, bis-(2,6-dichlorobenzoyl)-2,5-dimethylphenyl phosphine oxide, bis-(2,6-dichlorobenzoyl)-4-propylphenylphosphine oxide, bis-(2,6-dichlorobenzoyl)-1-naphthylphosphine oxide, bis-(2,6-dimethoxybenzoyl)phenylphosphine oxide, bis-(2,6-dimethoxybenzoyl)-2,4,4-trimethylpentylphosphine oxide, bis-(2,6-dimethoxy benzoyl)-2,5-dimethylphenylphosphine oxide, bis-(2,4,6-trimethylbenzoyl)-phenylphosphine oxide, 2,6-dimethoxybenzoyldiphenylphosphine oxide, 2,6-dichlorobenzoyldiphenylphosphine oxide, 2,4,6-trimethylbenzoylphenylphosphinic acid methyl ester, 2-methylbenzoyl diphenylphosphine oxide, pivaloylphenylphosphinic acid isopropyl ester, 2,4,6-trimethyl benzoyldiphenylphosphine oxide, ethyl-2,4,6-trimethylbenzoylphenylphosphinate, and (2,6-dimethoxybenzoyl)-2,4,4-pentyl phosphine oxide.

Commercially available acylphosphine oxide compounds such as Omnirad TPO, Omnirad TPO-L, LR8953X, and Omnirad 819, all of which are manufactured by IGM Resins, may be used.

The lower limit value of the content of the photopolymerization initiator (C) is preferably equal to or greater than 0.1% by mass, more preferably equal to or greater than 0.2% by mass, with respect to the entire mass of the epoxy resin (A) and the (meth)acrylate resin (B). The upper limit value of the content of the photopolymerization initiator (C) is preferably equal to or less than 15% by mass, more preferably equal to or less than 5% by mass, with respect to the entire mass of the epoxy resin (A) and the (meth)acrylate resin (B). Setting the content of the photopolymerization initiator (C) at a value falling within this range promotes curing of the resin composition for optical waveguides, and increases the chemical resistance of the cured product. In addition, this may also reduce the optical loss of the optical waveguide formed.

Other photopolymerization initiators may be used as long as the advantages of this embodiment are not impaired. As the photopolymerization initiators (C), only one type may be used by itself or two or more types may be in combination, whichever is appropriate.

In addition, a photopolymerization initiator (C) which exhibits high photosensitivity to a wavelength of the radiation to irradiate may be used as appropriate to adjust the content.

### <Additives>

The resin composition for optical waveguides may contain additional components other than the ones described above as long as the advantages of this embodiment are not impaired. Examples of the additional components include, without limitation, antioxidants, leveling agents, and solvents.

Examples of the phenolic antioxidants include AO-20, AO-30, AO-40, AO-50, AO-60, and AO-80, all of which are manufactured by ADEKA Corporation, and SUMILIZER GA-80 manufactured by Sumitomo Chemical Co., Ltd.

Examples of the phosphite antioxidants include PEP-8, PEP-36, HP-10, 2112, 1178, and 1500, all of which are manufactured by ADEKA Corporation, and JP-360 and JP-3CP both manufactured by Johoku Chemical Co., Ltd.

Examples of the sulfur-based antioxidants include AO-412S and AO-503 both manufactured by ADEKA Corporation, and SUMILIZER TP-D manufactured by Sumitomo Chemical Co., Ltd.

As the antioxidant, any of the compounds described above may be used by itself, or two or more compounds selected from those compounds may be used in combination, whichever is appropriate. Nevertheless, it is preferable that a phenolic antioxidant be used by itself. A highly heat-resistant optical waveguide may be formed advantageously by adding the antioxidant to the resin composition for optical waveguides.

The content of the antioxidant is preferably greater than 0% by mass, more preferably equal to or greater than 0.2% by mass, and even more preferably equal to or greater than 0.3% by mass, with respect to the entire mass of the resin composition for optical waveguides. The content of the antioxidant is preferably equal to or less than 5% by mass, more preferably equal to or less than 2% by mass, and even more preferably equal to or less than 1% by mass, with respect to the entire mass of the resin composition for optical waveguides. In a situation where any antioxidant is added, the heat resistance of the cured product could not be increased sufficiently if the antioxidant added were too little or too much. Specifically, if the antioxidant were added too little, then it would be difficult to achieve the expected effect even by adding the antioxidant and the heat resistance of the cured product could not be increased sufficiently. On the other hand, if the antioxidant were added too much, then the antioxidant would serve as a plasticizer, thus possibly causing a decline in the heat resistance of the cured product. In view of these considerations, a highly heat-resistant optical waveguide may be formed advantageously as long as the content of the antioxidant falls within the above-defined range.

As the leveling agent, any of various dispersants which are generally used as dispersants may be used. For example, PF-636 manufactured by OMNOVA Solutions may be used.

As can be seen from the foregoing description, the resin composition for optical waveguides according to this embodiment may be used effectively to form a highly heat-resistant optical waveguide.

### <Curing Method>

Any method may be used without limitation to cure the resin composition for optical waveguides as long as the method allows photocuring to advance. Specifically, a method in which the resin composition for optical waveguides is irradiated with a light ray having a wavelength of 365 nm and subjected to a heat treatment at 140° C. for 10 minutes may be used, for example. Note that the absorption wavelength and the heat treatment condition are not limited to any particular ones as long as the photocuring is allowed to advance.

Alternatively, a method in which the resin composition for optical waveguides is irradiated with a light ray with a wavelength of 365 nm at a UV exposure of 1000 mJ/cm² and subjected to a heat treatment at 140° C. for 10 minutes may also be used. Note that the absorption wavelength and heat-treatment condition are not limited to any particular ones as long as photocuring is allowed to advance.

Note that photocuring of the resin composition for optical waveguides according to this embodiment is also allowed to advance in the same manner, and an advantageous optical waveguide may also be formed, even by projection exposure using a photomask. Alternatively, the photocuring may also be advanced by using a light ray falling outside of the i-line range.

### 2. Dry Film for Optical Waveguides and Optical Waveguide

The resin composition for optical waveguides according to this embodiment may also be used as a material for a dry film for optical waveguides which is used when an optical waveguide is formed.

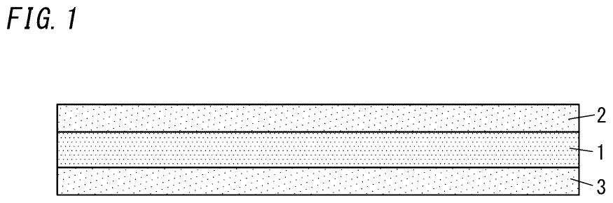

The dry film for use in optical waveguides (hereinafter simply referred to as a “dry film for optical waveguides”) according to this embodiment is not limited to any particular one as long as the dry film includes a resin layer 1 including either the resin composition for optical waveguides or a semi-cured product of the resin composition for optical waveguides. Specifically, the dry film for optical waveguides may include a film base member 2 on one surface of the resin layer 1 and a protective film 3 on the other surface of the resin layer 1 as shown in FIG. 1. Note that the dry film for optical waveguides only needs to include the resin layer 1 and may include not only the film base member 2 and the protective film 3 but also other layers as well. Note that the film base member 2 and the protective film 3 are not essential constituent elements. FIG. 1 is a cross-sectional view illustrating a configuration for a dry film for optical waveguides according to this embodiment.

The resin layer 1 contains the resin composition for optical waveguides or a semi-cured product thereof. The resin layer 1 is formed out of the resin composition for optical waveguides according to this embodiment, and therefore, has reduced tackiness, thus improving the processibility.

The thickness of the resin layer 1 is preferably adjusted appropriately but is preferably equal to or greater than 20 μm, and more preferably equal to or greater than 30 μm, for example. The thickness of the resin layer 1 is preferably equal to or less than 100 μm, and more preferably equal to or less than 80 μm. Setting the thickness of the resin layer 1 at a value falling within this range allows the cured product to have sufficient mechanical strength and allows an optical waveguide to be formed advantageously.

The film base member 2 is not limited to any particular one. Examples of the film base member 2 include: polyesters such as polyethylene terephthalate, polybutylene terephthalate, and polyethylene naphthalate; polyolefins such as polyethylene and polypropylene; polycarbonate, polyamide, polyimide, polyamideimide, polyetherimide, polyethersulfide, polyethersulfone, polyetherketone, polyphenylene ether, polyphenylene sulfide, polyarylate, polysulfone, and liquid crystal polymers. It is preferable to use any one selected from the group consisting of polyethylene terephthalate, polybutylene terephthalate, polyethylene naphthalate, polypropylene, polycarbonate, polyamide, polyimide, polyamideimide, polyphenylene ether, polyphenylene sulfide, polyarylate, and polysulfone, all of which have excellent flexibility and toughness.

The thickness of the film base member 2 is preferably adjusted appropriately, but is preferably, for example, equal to or greater than 3 μm and equal to or less than 250 μm. Setting the thickness of the film base member 2 at such a value allows for manufacturing a dry film for optical waveguides having an excellent film strength and flexibility. Consequently, this improves the processability of the dry film for optical waveguides to the point that an advantageous optical waveguide may be formed easily.

In addition, a peeling treatment may be performed, using a fluorine-containing compound, for example, on the surface of the film base member 2 which contacts with the resin layer 1. Performing the peeling treatment allows the resin layer 1 to be peeled off easily from the film base member 2.

The protective film 3 is not limited to any particular one. Examples of the protective film 3 include: polyesters such as polyethylene terephthalate, polybutylene terephthalate, and polyethylene naphthalate; and polyolefins such as polyethylene and polypropylene. Among other things, polyesters such as polyethylene terephthalate having excellent flexibility and toughness; and polyolefins such as polyethylene and polypropylene are preferred.

The thickness of the protective film 3 is preferably adjusted appropriately, but is preferably, for example, equal to or greater than 10 μm and equal to or less than 250 μm. Setting the thickness of the protective film 3 at a value falling within this range allows a dry film for optical waveguides having excellent film strength and flexibility to be manufactured. Consequently, this improves the processability of the dry film for optical waveguides to the point that an advantageous optical waveguide may be formed easily. Also, a peeling treatment may be carried out in the same manner as in the film base member 2.

A method for forming the dry film for optical waveguides may be, without limitation, the following method, for example. First, a solvent, for example, is added to the resin composition for optical waveguides to turn the resin composition and the solvent into varnish. The varnish is then applied onto the film base member 2. The varnish may be applied, for example, using a comma coater. The varnish is dried, thereby forming a resin layer 1 including the resin composition for optical waveguides on the film base member 2. Then, a protective film 3 is further stacked on the resin layer 1. A thermal laminating method, for example, may be used as a method for stacking the protective film 3. The resin layer 1 included in the dry film for optical waveguides is used as a material for the optical waveguide. The dry film for optical waveguides may be used to form the core of the optical waveguide or the cladding, whichever is appropriate.

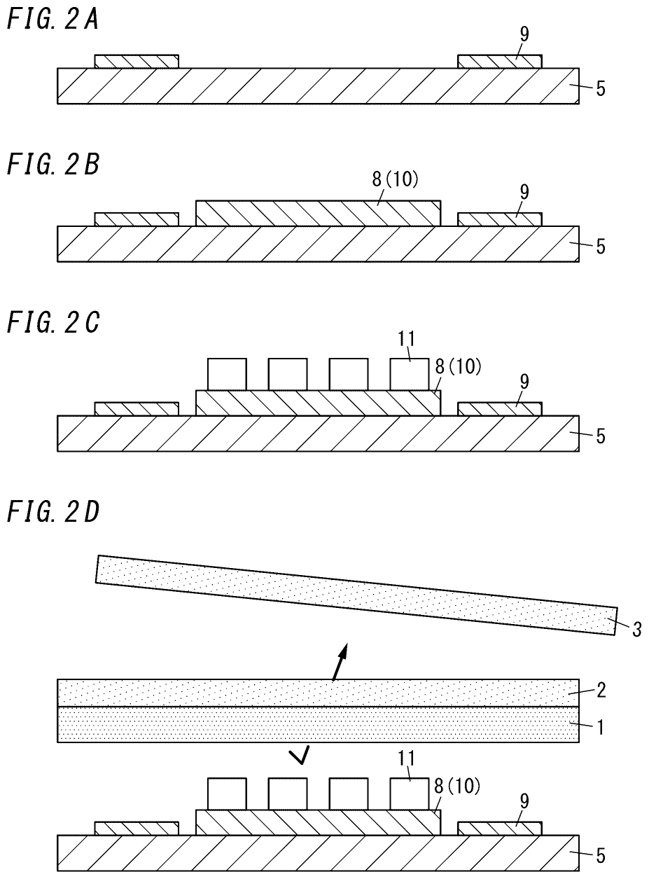

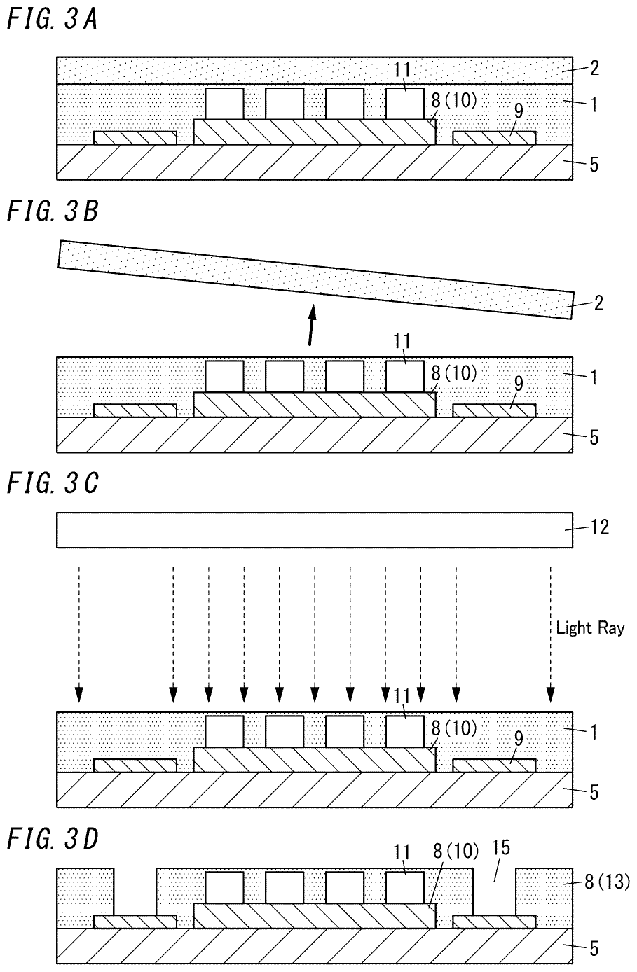

A method for forming an optical waveguide according to this embodiment will now be described with reference to FIGS. 2A-2D and FIGS. 3A-3D. In the following description, a method for manufacturing a hybrid optical-electrical board including the optical waveguide will be described. Note that FIGS. 2A-2D and FIGS. 3A-3D illustrate a method for manufacturing a hybrid optical-electrical board including the optical waveguide according to this embodiment.

First, as shown in FIG. 2A, a board 5 including an electric circuit 9 is provided. Next, as shown in FIG. 2B, a cladding layer 8 (lower cladding layer 10) is formed on the surface of the board 5 on which the electric circuit 9 is provided. Any method may be used without limitation as a method for forming the lower cladding layer 10. For example, a method in which a dry film for optical waveguides is laid on top of the board 5 and has its entire surface irradiated with light, thereby curing the film, may be used.

Next, as shown in FIG. 2C, cores 11 are formed on the lower cladding layer 10. Any method may be used without limitation as a method for forming the cores 11 as long as the resin composition for optical waveguides according to this embodiment is used. For example, a method in which a dry film for optical waveguides containing either a resin composition for optical waveguides or a semi-cured product thereof is laid on top of the lower cladding layer 10, is cured by performing a process of irradiating only a selected region with light, and then an uncured portion thereof is removed with an alkaline developer, may be used.

Next, a cladding layer 8 (upper cladding layer 13) is formed out of the dry film for optical waveguides (refer to FIG. 3D). Specifically, as shown in FIG. 2D, the protective film 3 is peeled off from the dry film for optical waveguides. Thereafter, as shown in FIG. 3A, the dry film for optical waveguides is stacked on the assembly such that the resin layer 1 thereof covers the lower cladding layer 10 and the cores 11. Subsequently, as shown in FIG. 3B, the film base member 2 is peeled off from the dry film for optical waveguides.

Next, as shown in FIG. 3C, the resin layer 1 is irradiated with a light ray emitted from a light source 12 at a wavelength of 365 nm, thereby photocuring the resin composition for optical waveguides. This turns the resin layer 1 into an upper cladding layer 13. Note that via holes 15 may be formed as shown in FIG. 3D by irradiating the entire resin layer 1 but its parts to be via holes 15 with the light ray having the wavelength of 365 nm as shown in FIG. 3C and then developing the resin layer 1.

An optical waveguide may be formed in this manner using the dry film for optical waveguides according to this embodiment. That is to say, the optical waveguide shown in FIG. 3D includes the cores 11, the lower cladding layer 10, and the upper cladding layer 13. The upper cladding layer 13 covers the cores 11. The upper cladding layer 13 is a cured product of the resin composition for optical waveguides.

Although the dry film for optical waveguides is used in this embodiment to form the upper cladding layer 13, the lower cladding layer 10, and the cores 11, one or two selected from the group consisting of the upper cladding layer 13, the lower cladding layer 10, and the cores 11 may also be formed by using another dry film.

As can be seen from the foregoing description, the dry film for optical waveguides according to this embodiment includes the resin layer 1 containing the resin composition for optical waveguides. Also, the optical waveguide according to this embodiment includes a core 11 and a cladding layer 8 that covers the core 11. At least one of the core 11 or the cladding layer 8 includes a cured product of the resin composition for optical waveguides.

### 3. Aspects

As can be seen from the foregoing description of embodiments, the present disclosure has the following aspects. In the following description, reference signs are added in parentheses to the respective constituent elements solely for the purpose of clarifying the correspondence between the following aspects of the present disclosure and the embodiments described above.

A first aspect is a resin composition for use in optical waveguides. The resin composition contains an epoxy resin (A), a (meth)acylate resin (B), and a photopolymerization initiator (C). The (meth)acrylate resin (B) includes: a first (meth)acrylate compound (B-1) having a structural unit expressed by the following formula (1) and a structural unit expressed by the following formula (2); and a second (meth)acrylate compound (B-2) different from the first (meth)acrylate compound (B-1). The content of the first (meth)acrylate compound (B-1) is equal to or greater than 5% by mass and equal to or less than 20% by mass with respect to an entire mass of the epoxy resin (A) and the (meth)acrylate resin (B). The content of the second (meth)acrylate compound (B-2) is equal to or greater than 30% by mass and equal to or less than 80% by mass with respect to the entire mass of the epoxy resin (A) and the (meth)acrylate resin (B).

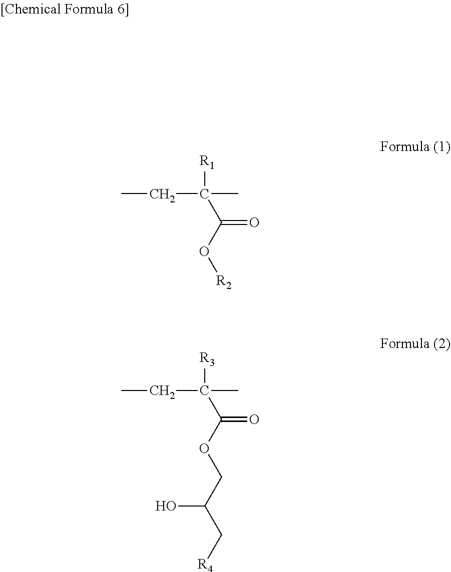

In formulae (1) and (2), R₁ to R₃ are each independently an alkyl group having 1 to 3 carbon atoms or a hydrogen atom, and R₄ is an acryloyl group or a methacryloyl group.

This aspect allows the resin composition for use in optical waveguides to achieve excellent alkaline developability and low tackiness at the same time.

A second aspect is a resin composition for use in optical waveguides which may be implemented in conjunction with the first aspect. In the second aspect, the epoxy resin (A) contains at least one selected from the group consisting of a solid bisphenol A epoxy compound (A-1), a liquid bisphenol A epoxy compound (A-2), and a polyfunctional aromatic epoxy compound (A-3) having three or more epoxy groups per molecule on average.

A third aspect is a resin composition for use in optical waveguides which may be implemented in conjunction with the first or second aspect. In the third aspect, the (meth)acrylate resin (B) further includes at least one selected from the group consisting of a urethane (meth)acrylate compound (B-21) and a bisphenol A (meth)acrylate compound (B-22).

A fourth aspect is a resin composition for use in optical waveguides which may be implemented in conjunction with any one of the first to third aspects. In the fourth aspect, the first (meth)acrylate compound (B-1) includes a (meth)acrylate compound (B-11) having a structural unit expressed by the following formula (3) and a structural unit expressed by the following formula (4):

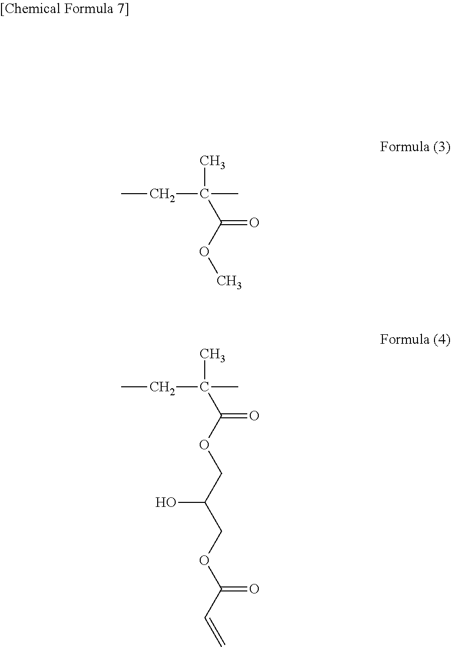

This aspect allows for further reducing the tackiness.

A fifth aspect is a resin composition for use in optical waveguides which may be implemented in conjunction with any one of the second to fourth aspects. In the fifth aspect, the content of the solid bisphenol A epoxy compound (A-1) is equal to or greater than 40% by mass and equal to or less than 60% by mass with respect to an entire mass of the epoxy resin (A).

A sixth aspect is a resin composition for use in optical waveguides which may be implemented in conjunction with any one of the second to fifth aspects. In the sixth aspect, the content of the liquid bisphenol A epoxy compound (A-2) is equal to or greater than 15% by mass and equal to or less than 30% by mass with respect to an entire mass of the epoxy resin (A).

A seventh aspect is a resin composition for use in optical waveguides which may be implemented in conjunction with any one of the second to sixth aspects. In the seventh aspect, the content of the polyfunctional aromatic epoxy compound (A-3) is equal to or greater than 15% by mass and equal to or less than 30% by mass with respect to an entire mass of the epoxy resin (A).

An eighth aspect is a resin composition for use in optical waveguides which may be implemented in conjunction with any one of the first to seventh aspects. In the eighth aspect, the photopolymerization initiator (C) includes an acylphosphine oxide compound (C1).

A ninth aspect is a dry film for use in optical waveguides. The dry film includes a resin layer (1) containing either the resin composition for use in optical waveguides according to any one of the first to eighth aspects or a semi-cured product of the resin composition for use in optical waveguides.

This aspect allows excellent alkaline developability and low tackiness to be achieved at the same time.

A tenth aspect is a dry film for use in optical waveguides which may be implemented in conjunction with the ninth aspect. In the eleventh aspect, the dry film further includes at least one film selected from the group consisting of a film base member (2) and a protective film (3).

An eleventh aspect is an optical waveguide which includes a core (11) and a cladding layer (8; 10, 13) that covers the core (11). At least one of the core (11) or the cladding layer (8; 10, 13) contains a cured product of the resin composition for use in optical waveguides according to any one of the first to eighth aspects.

### EXAMPLES

Next, specific examples of the present disclosure will be described. Note that the examples to be described below are only examples of the present disclosure and should not be construed as limiting.

### [Epoxy Resin (A)]

Solid bisphenol A epoxy compound (A-1), product name: JER-1006FS manufactured by Mitsubishi Chemical Corporation, having an epoxy equivalent of 900 to 1100 g/eq;
Liquid bisphenol A epoxy compound (A-2), product name: 850-S manufactured by DIC Corporation, having an epoxy equivalent of 183 to 193 g/eq; and
Polyfunctional aromatic epoxy compound (A-3), product name: VG3101 manufactured by Printec Co., Ltd., having an epoxy equivalent of 205 to 215 g/eq.

### [(Meth)Acrylate Resin (B)]

First (meth)acrylate compound (B-1), product name: V-6850 manufactured by DIC Corporation;
Urethane (meth)acrylate compound (B-21), product name: UXE-3024 manufactured by Nippon Kayaku Co., Ltd.;
Bisphenol A (meth)acrylate compound (B-22), product name: EA-1010LC manufactured by Shin-Nakamura Chemical Co., Ltd.; and
Other (meth)acrylate compounds, product name: PET-30 manufactured by DKS Co. Ltd.

### [Photopolymerization Initiator (C)]

Acylphosphine oxide compound (C-1), product name: Omnirad 819 manufactured by IGM Resins B.V.

### [Additives]

Antioxidant, product name: AO-60 manufactured by ADEKA Corporation; and
Leveling agent, product name: PF-636 manufactured by OMNOVA Solutions.

### [Resin Composition for Optical Waveguides]

Examples 1 and 2 and Comparative Examples 1 and 2 of resin compositions for optical waveguides were prepared as follows. First, respective materials was weighed into a glass container to have any of the chemical makeups (in parts by mass) shown in Table 1, and 2-butanone, toluene, and propylene glycol monomethyl ether acetate were added thereto as solvents at a ratio of 7:2:1. The mixture was then stirred up under a reflux at 80° C. to obtain a uniform varnish-like composition in which all soluble solids were dissolved. The varnish-like composition thus obtained was filtered through a membrane filter made of polytetrafluoroethylene (PTFE) with a pore diameter of 1 μm. In this manner, the solid foreign matter contained therein was removed. The varnish-like resin composition for optical waveguides thus filtered was used after that. [Dry film for optical waveguides]

Next, a dry film was produced by using the resin compositions for optical waveguide according to Examples 1 and 2 and Comparative Examples 1 and 2. The varnish-like resin composition for optical waveguides obtained as described above was applied onto a PET film (product name: A4100 manufactured by Toyobo Co., Ltd.) as a film base member by using a multi-coater with a comma coater head manufactured by Hirano Tecseed Co., Ltd. so that a resin layer containing the resin composition for optical waveguides would have a thickness of 50 μm, and then dried at 80° C. for 30 minutes. In this manner, a resin layer containing the resin composition for optical waveguides was formed to a thickness of 50 μm on the PET film.

### [Alkaline Developability]

The dry film for optical waveguides prepared as described above was immersed in an aqueous solution of sodium carbonate (with a concentration of 1%) for 10 minutes, and then the condition of the dry film for optical waveguides was observed. The dry film was evaluated in terms of alkaline developability based on the following criteria:
Grade A: if no resin layer was left on the film base member; or
Grade B: if any resin layer was left on the film base member.

### <Tackiness>

The dry film for optical waveguides thus produced was evaluated in terms of the degree of tackiness on its surface. The tackiness was determined by the following criteria based on a sense of touch that the tester felt when he or she put a finger on the dry film:
Grade A: if no finger marks were left on the surface; or
Grade B: if any finger marks were left on the surface.

TABLE 1

| | | | | | | Cmp. | Cmp. |
|---|---|---|---|---|---|---|---|
| | | | | Ex. 1 | Ex. 2 | Ex. 1 | Ex. 2 |
| Resin | Epoxy resin (A) | Solid bisphenol A epoxy | parts | 20 | 20 | 20 | 20 |
| (Composition | | compound (A-1) | by mass | | | | |
| ratio) | | Liquid bisphenol A epoxy | parts | 10 | 10 | 10 | 10 |
| | | compound (A-2) | by mass | | | | |
| | | Polyfunctional aromatic epoxy | parts | 10 | 10 | 10 | 10 |
| | | compound (A-3) | by mass | | | | |
| | (Meth)acrylate | (Meth)acrylate compound (B-1) | parts | 10 | 20 | 0 | 50 |
| | resin (B) | | by mass | | | | |
| | | Urethane (meth)acrylate | parts | 40 | 40 | 40 | 40 |
| | | compound (B-21) | by mass | | | | |
| | | Bisphenol A (meth)acrylate | parts | 10 | 10 | 10 | 10 |
| | | compound (B-22) | by mass | | | | |
| | | Other acrylate compounds | parts | 10 | 10 | 10 | 10 |
| | | | by mass | | | | |
| | Photopolymerization | Acylphosphine oxide compound (C-1) | parts | 0.1 | 0.1 | 0.1 | 0.1 |
| | Initiator (C) | | by mass | | | | |
| | Additives | Antioxidant | parts | 0.3 | 0.3 | 0.3 | 0.3 |
| | | | by mass | | | | |
| | | Leveling agent | parts | 0.1 | 0.1 | 0.1 | 0.1 |
| | | | by mass | | | | |

| Content of (meth)acrylate compound (B-1) | parts | 9 | 17 | 0 | 33 |
|---|---|---|---|---|---|
| | by mass | | | | |
| Content of (meth)acrylate compound (B-2) | parts | 55 | 50 | 60 | 40 |
| | by mass | | | | |

| Items of evaluation | Tackiness | A | A | B | A |
|---|---|---|---|---|---|
| | Alkaline developability | A | A | A | B |

### REFERENCE SIGNS LIST

1 Resin Layer
2 Film Base Member
3 Protective Film
8 Cladding Layer
11 Core

1. A resin composition for use in optical waveguides, the resin composition containing an epoxy resin (A), a (meth)acylate resin (B), and a photopolymerization initiator (C),
the (meth)acrylate resin (B) including: a first (meth)acrylate compound (B-1) having a structural unit expressed by the following formula (1) and a structural unit expressed by the following formula (2); and a second (meth)acrylate compound (B-2) different from the first (meth)acrylate compound (B-1),
content of the first (meth)acrylate compound (B-1) being equal to or greater than 5% by mass and equal to or less than 20% by mass with respect to an entire mass of the epoxy resin (A) and the (meth)acrylate resin (B), and
content of the second (meth)acrylate compound (B-2) being equal to or greater than 30% by mass and equal to or less than 80% by mass with respect to the entire mass of the epoxy resin (A) and the (meth)acrylate resin (B), 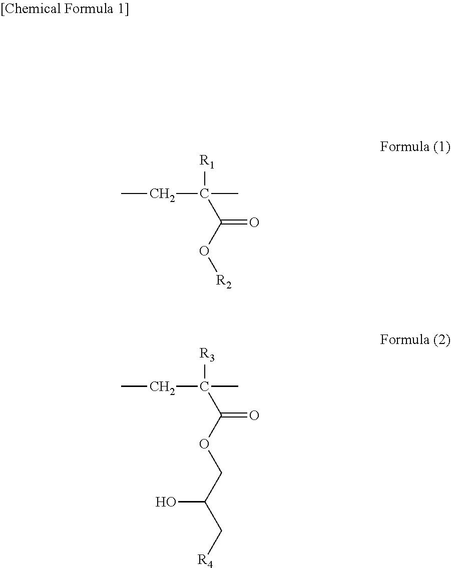
where in formulae (1) and (2), R₁ to R₃ are each independently an alkyl group having 1 to 3 carbon atoms or a hydrogen atom, and R₄ is an acryloyl group or a methacryloyl group.

2. The resin composition of claim 1, wherein
the epoxy resin (A) contains at least one selected from the group consisting of a solid bisphenol A epoxy compound (A-1), a liquid bisphenol A epoxy compound (A-2), and a polyfunctional aromatic epoxy compound (A-3) having three or more epoxy groups per molecule on average.

3. The resin composition of claim 1, wherein
the (meth)acrylate resin (B) further includes at least one selected from the group consisting of a urethane (meth)acrylate compound (B-21) and a bisphenol A (meth)acrylate compound (B-22).

4. The resin composition of claim 1, wherein
the first (meth)acrylate compound (B-1) includes a (meth)acrylate compound (B-11) having a structural unit expressed by the following formula (3) and a structural unit expressed by the following formula (4):

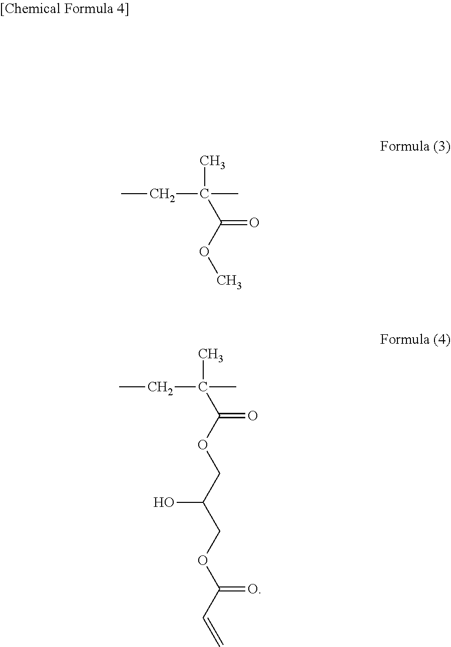

5. The resin composition of claim 2, wherein
content of the solid bisphenol A epoxy compound (A-1) is equal to or greater than 40% by mass and equal to or less than 60% by mass with respect to an entire mass of the epoxy resin (A).

6. The resin composition of claim 2, wherein
content of the liquid bisphenol A epoxy compound (A-2) is equal to or greater than 15% by mass and equal to or less than 30% by mass with respect to an entire mass of the epoxy resin (A).

7. The resin composition of claim 2, wherein
content of the polyfunctional aromatic epoxy compound (A-3) is equal to or greater than 15% by mass and equal to or less than 30% by mass with respect to an entire mass of the epoxy resin (A).

8. The resin composition of claim 1, wherein
the photopolymerization initiator (C) includes an acylphosphine oxide compound (C-1).

9. A dry film for use in optical waveguides, the dry film comprising a resin layer containing either the resin composition of claim 1 or a semi-cured product of the resin composition.

10. The dry film of claim 9, further comprising at least one film selected from the group consisting of a film base member and a protective film.

11. An optical waveguide comprising a core and a cladding layer that covers the core,
at least one of the core or the cladding layer containing a cured product of the resin composition of claim 1.
